(19) United States
(12) Patent Application Publication
(10) Pub. No.: US 2016/0133446 A1
(43) Pub. Date: May 12, 2016

(54) MOVING MAGNET ASSEMBLY TO INCREASE THE UTILITY OF A RECTANGULAR MAGNETRON SPUTTERING TARGET

(71) Applicant: Proportional Technologies, Inc., Houston, TX (US)

(72) Inventors: Jeffrey L. Lacy, Houston, TX (US); Murari Regmi, Houston, TX (US)

(21) Appl. No.: 14/939,296

(22) Filed: Nov. 12, 2015

Related U.S. Application Data
(60) Provisional application No. 62/078,877, filed on Nov. 12, 2014.

(51) Int. Cl. H01J 37/34; C23C 14/35

(52) U.S. Cl. CPC H01J 37/3455; H01J 37/3408; C23C 14/35; H01J 2237/332

(57) ABSTRACT

A method and apparatus is disclosed for improved magnetron sputtering utilizing a movable magnet. Preferably, the apparatus can be used to move the magnet along any two dimensional paths within the range of the moving stages. In one preferred method for sputtering a coating using a magnetron sputtering apparatus comprises the step of moving a magnet assembly in two dimensions during the sputtering process to allow increased erosion area of the target as compared to stationary magnets. In another preferred embodiment the invention includes a magnetron sputtering apparatus comprising a first motion stage allowing movement in a first direction, a second motion stage allowing movement in second direction, a magnet assembly operably attached to said first and second motion stages, and a control unit, wherein said first motion stage moves in a general first direction and second motion stage moves in a generally second direction which is generally orthogonal and wherein said control unit controls the movement of the motion stages.

### RELATED APPLICATIONS

This application claims priority to U.S. Provisional Application No. 62/078,877 (“the '877 Application”) filed Nov. 12, 2014. The '877 Application is hereby incorporated by reference in its entirety for all purposes, including but not limited to, all portions describing the process of the present invention, those portions describing boron-coated straw detectors in general as background and for use with specific embodiments of the present invention, and those portions describing other aspects of manufacturing and testing of boron-coated straws that may relate to the present invention.

### GOVERNMENTAL SPONSORSHIP

This invention was made with support under HDTRA1-14-C-0110 awarded by the Defense Threat Reduction Agency. The government may have certain rights in the invention.

### REFERENCE TO A SEQUENTIAL LISTING

Not applicable.

### BACKGROUND OF THE INVENTION

1. Field of the Invention

This invention relates to magnetron sputtering. More particularly, this invention relates to the design of a magnetron sputtering system that includes moving the system magnets.

2. Description of the Related Art

Magnetron sputtering is form of physical vapor deposition (PVD) coating technology. Magnetron sputtering is a plasma coating process whereby sputtering material is ejected due to bombardment of ions to the target surface. The vacuum chamber of the PVD coating machine is filled with an inert gas, such as argon. By applying a high voltage, a glow discharge is created, resulting in acceleration of ions to the target surface and a plasma coating. The argon-ions will eject sputtering materials from the target surface (sputtering), resulting in a sputtered coating layer on the products in front of the target.

In magnetron sputtering, magnetic fields are used to locally trap the electrons in the plasma and hence increase the ion current density. Higher density of trapped electrons causes orders of magnitude increase of the ionization rate of the gas atoms, usually Argon, and consequently increasing the thin film deposition rate. However, the increased deposition rate comes with a price. Because of the localized nature of the trapped electrons in a narrow space, only the material from this narrow region, usually called the race track, of the magnetron sputtering targets is used for the deposition of the thin films.

Different kinds of magnet assembly design such as profiled magnets or use of moving magnet assembly has been suggested to increase the utility of the target material. By moving a magnet of appropriate size along an optimal path with an appropriate speed, the use of the target material can be significantly enhanced. In the past, magnet assembly were moved along a path dictated by the mechanical design of the driving system such that only some specific paths allowed by the driving system were possible. Because of this limitation an optimal two dimensional moving path for the magnet assembly could not be designed.

Boron-coated straw detector technology was first patented by Dr. Lacy in U.S. Pat. No. 7,002,159 entitled “Boron-Coated Straw Neutron Detector” based upon a Nov. 13, 2002, filing. As the thought leader of this technology area, Dr. Lacy continued his research and development to improve the boron coated straw detectors technology and to find new uses. Examples of Dr. Lacy's continued progress in this technology area are found in his other issued patents and pending patent applications which include: U.S. Pat. No. 8,330,116 entitled “Long Range Neutron-Gamma Point Source Detection and Imaging Using Rotating Detector”; U.S. Pat. No. 8,569,710 entitled “Optimized Detection of Fission Neutrons Using Boron-Coated Straw Detectors Distributed in Moderator Material”; U.S. Pat. No. 8,907,293, entitled “Optimized Detection of Fission Neutrons Using Boron-Coated Straw Detectors Distributed in Moderator Material”; U.S. patent application Ser. No. 13/106,785 filed May 12, 2011, entitled “Sealed Boron-Coated Straw Detectors” (allowed and issue fee paid); U.S. patent application Ser. No. 13/106,818 filed May 12, 2011, entitled “Neutron Detectors for Active Interrogation” (allowed and issue fee paid); U.S. Pat. No. 8,941,075, entitled “Boron Coated Straw Detectors with Shaped Straws”; U.S. application Ser. No. 14/060,015 filed Oct. 22, 2013, entitled “Method and Apparatus for Coating Thin Foil with a Boron Coating”; and U.S. application Ser. No. 14/060,507 filed Oct. 22, 2013, entitled “Method and Apparatus for Fabrication Boron Coated Straws for Neutron Detectors.” The patent and pending applications mentioned in this paragraph are hereby incorporated by reference in their entirety for all purposes, including but not limited to those portions describing the structure and technical details of the boron-coated straw detectors and boron coating as background and for use as specific embodiments of the present invention, and those portions describing other aspects of manufacturing and testing of boron-coated straws that may relate to the present invention.

Dr. Lacy also widely published articles on boron-coated straw detection capabilities, fabrication, and development of prototypes for various applications including:

J. L. Lacy, et al, “Novel neutron detector for high rate imaging applications”, IEEE Nuclear Science Symposium Conference Record, 2002, vol. 1, pp. 392-396;
J. L. Lacy, et al, “Straw detector for high rate, high resolution neutron imaging”, in IEEE Nuclear Science Symposium Conference Record, 2005, vol. 2, pp. 623-627;
J. L. Lacy, et al, “High sensitivity portable neutron detector for fissile materials detection”, IEEE Nuclear Science Symposium Conference Record, 2005, vol. 2, pp. 1009-1013;

### J. L. Lacy, et al, “Performance of 1 Meter Straw Detector for High Rate Neutron Imaging”, IEEE Nuclear Science Symposium Conference Record, 2006, vol. 1, pp. 20-26;

J. L. Lacy, et al, “Long range neutron-gamma point source detection and imaging using unique rotating detector”, IEEE Nuclear Science Symposium Conference Record, 2007, vol. 1, pp. 185-191;
J. L. Lacy, et al, “Fabrication and materials for a long range neutron-gamma monitor using straw detectors”, IEEE Nuclear Science Symposium Conference Record, 2008, pp. 686-691;
J. L. Lacy, et al, “One meter square high rate neutron imaging panel based on boron straws”, IEEE Nuclear Science Symposium Conference Record, 2009, pp. 1117-1121;
J. L. Lacy, et al, “Boron coated straw detectors as a replacement for ³He”, IEEE Nuclear Science Symposium Conference Record, 2009, pp. 119-125;
J. L. Lacy, et al, “One meter square high rate neutron imaging panel based on boron straws”, IEEE 2009 Nuclear Science Symposium Conference Record, 2009, pp. 1117-1121;
J. L. Lacy, et al, “Initial performance of large area neutron imager based on boron coated straws”, IEEE 2010 Nuclear Science Symposium Conference Record, 2010, pp. 1786-1799;
J. L. Lacy, et al, “Initial performance of sealed straw modules for large area neutron science detectors”, IEEE 2011 Nuclear Science Symposium Conference Record, 2011, pp. 431-435;
J. L. Lacy, et al, “Straw-Based Portal Monitor ³He Replacement Detector with Expanded Capability”, IEEE 2011 Nuclear Science Symposium Conference Record, 2011, pp. 431-435;

### J. L. Lacy, et al, “Performance of a Straw-Based Portable Neutron Concidence/Multiplicity Counter”, IEEE 2011 Nuclear Science Symposium Conference Record, 2011, pp. 529-532;

### J. L. Lacy, et al, “Replacement of ³He in Constrained-Volume Homeland Security Detectors”, IEEE 2011 Nuclear Science Symposium Conference Record, 2011, pp. 324-325;

J. L. Lacy, et al, “Initial performance of sealed straw modules for large area neutron science detectors”, IEEE 2011 Nuclear Science Symposium Conference Record, 2011, pp. 431-435;
J. L. Lacy, et al, “Boron-coated straws as a replacement for 3He-based neutron detectors”, Nuclear Instruments and Methods in Physics Research, Vol. 652, 2011, pp. 359-363;

### J. L. Lacy, et al, “Design and Performance of High-Efficiency Counters Based on Boron-Lined Straw Detectors”, Institute of Nuclear Materials Management Annual Proceedings, 2012;

J. L. Lacy, et al, “Boron-coated straw detectors of backpack monitors”, IEEE Transactions on Nuclear Science, Vol. 60, No. 2, 2013, pp. 1111-1117.

### J. L. Lacy, et al, “The Evolution of Neutron Straw Detector Applications in Homeland Security”, IEEE Transactions on Nuclear Science, Vol. 60, No. 2, 2013, pp. 1140-1146.

The publications mentioned in this paragraph are hereby incorporated by reference in their entirety for all purposes, including but not limited to those portions describing the structure and technical details of the boron-coated straw detectors and boron coatings as background and for use as specific embodiments of the present invention, and those portions describing other aspects of manufacturing and testing of boron-coated straws that may relate to the present invention.

### SUMMARY OF THE INVENTION

This present invention includes a method and apparatus for improved magnetron sputtering utilizing a movable magnet. Preferably, the apparatus can be used to move the magnet along any two dimensional paths within the range of the moving stages. In one preferred method for sputtering a coating using a magnetron sputtering apparatus comprises the step of moving a magnet assembly in two dimensions during the sputtering process to allow increased erosion area of the target as compared to stationary magnets. In another preferred embodiment the invention includes a magnetron sputtering apparatus comprising a first motion stage allowing movement in a first direction, a second motion stage allowing movement in second direction, a magnet assembly operably attached to said first and second motion stages, and a control unit, wherein said first motion stage moves in a general first direction and second motion stage moves in a generally second direction which is generally orthogonal and wherein said control unit controls the movement of the motion stages.

Additional advantages of the invention are set forth in part in the description which follows, and in part will be obvious from the description, or may be learned by practice of the invention. The advantages of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF SEVERAL VIEWS OF THE DRAWINGS

A better understanding of the invention can be obtained when the detailed description set forth below is reviewed in conjunction with the accompanying drawings, in which:

FIG. 1 depicts a design for a rectangular magnetron gun such as is known in the art and associated plasma profiles from different orientations.

FIG. 2 depicts a magnetic field generated from a magnetron such as the design of FIG. 1.

FIG. 3 depicts a profile of the narrow region of target erosion generated by a magnetron such as shown in FIG. 1.

FIG. 4 depicts a profile of target erosion generated in an ideal situation.

FIG. 5 depicts a schematic of the motion stages of a preferred embodiment of the present invention.

FIG. 6 depicts a schematic showing preferred movement range of a magnet assembly.

FIG. 7 depicts preferred motion paths for magnet assemblies utilized by preferred embodiments of the present invention.

FIG. 8 depicts a profile of target erosion generated in a preferred embodiment of the present invention.

FIG. 9 depicts a comparison of target profiles (side views) from conventional system and from an embodiment of the present invention with a moving magnet.

FIG. 10 depicts another comparison of the results achieved using a conventional system and an embodiment of the present invention with a moving magnet.

### DETAILED DESCRIPTION OF VARIOUS EMBODIMENTS OF THE INVENTION

This present invention includes a method and apparatus for improved magnetron sputtering utilizing a movable magnet. Preferably, the apparatus can be used to move the magnet along any two dimensional paths within the range of the moving stages. In one preferred method for sputtering a coating using a magnetron sputtering apparatus comprises the step of moving a magnet assembly in two dimensions during the sputtering process to allow increased erosion area of the target as compared to stationary magnets. In another preferred embodiment the invention includes a magnetron sputtering apparatus comprising a first motion stage allowing movement in a first direction, a second motion stage allowing movement in second direction, a magnet assembly operably attached to said first and second motion stages, and a control unit, wherein said first motion stage moves in a general first direction and second motion stage moves in a generally second direction which is generally orthogonal and wherein said control unit controls the movement of the motion stages.

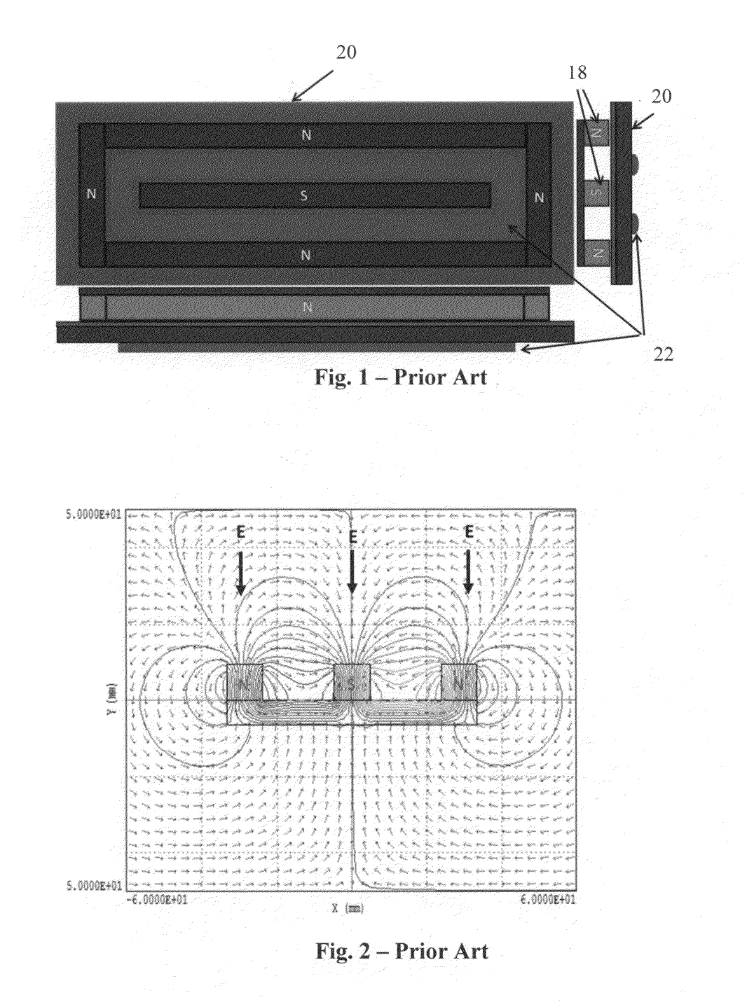

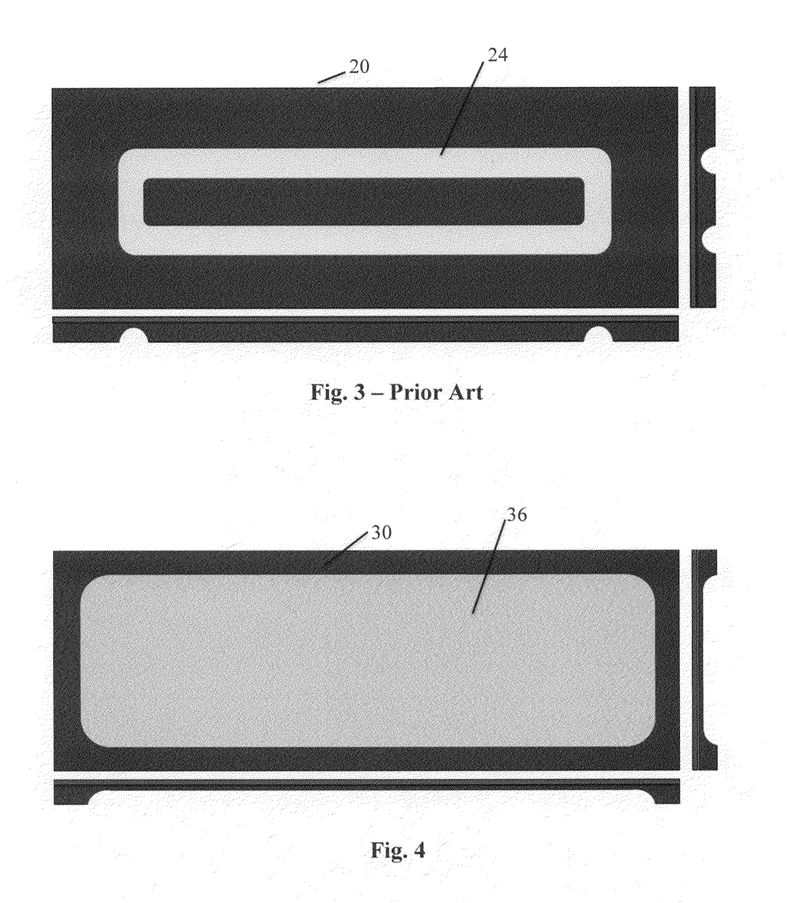

A typical design for a rectangular magnetron gun and associated plasma profiles from different orientations are shown in FIG. 1 and FIG. 2. As can be seen, such a system includes magnets 18, plasma 22, and target 20. The electric field E is perpendicular on the target surface but the magnetic field changes direction at different locations. Maximum ionization only takes place in the region just above the target surface where the electric field E and the magnetic field are orthogonal to each other. In this case the magnetic field becomes parallel to the target surface. The direction of the magnetic field is shown by small arrows in FIG. 2. Because of such very localized but intense plasma, targets 20 gets eroded from a very narrow region 24, profile shown in FIG. 3, making most of the target material unusable.

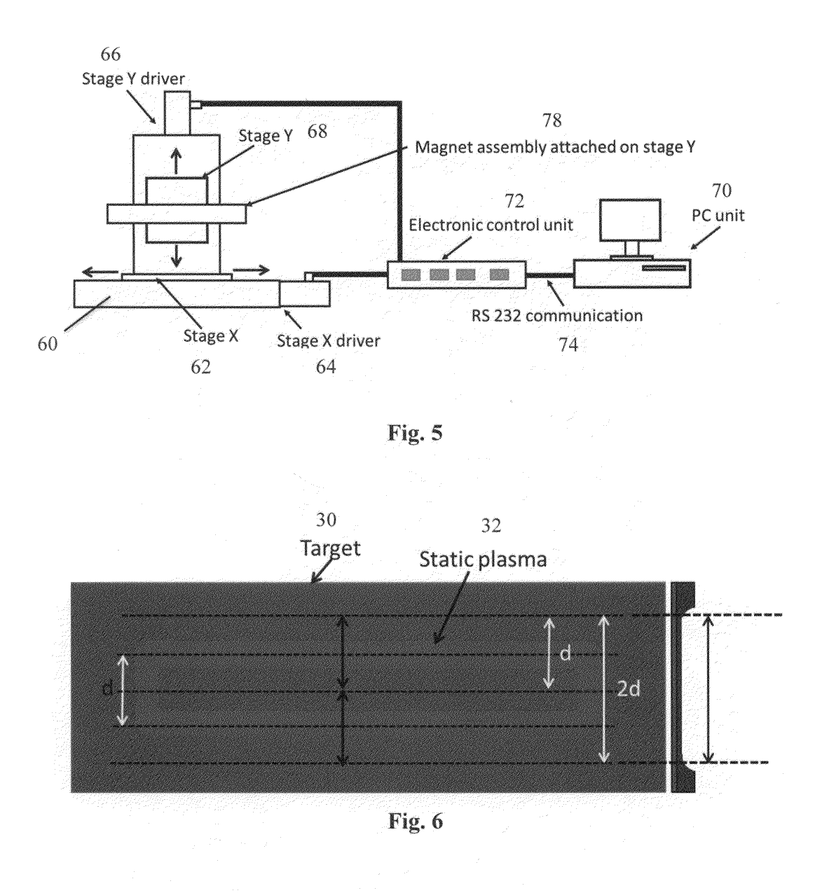

In a preferred embodiment of the present invention, a moving magnet assembly is utilized, as opposed to having fixed magnets as are known in the art, to allow the plasma to equally scan through the two dimensional target surface to ideally create the target profile as shown in FIG. 4. As can be seen, target 30 has a substantially larger eroded portion 36 that shown in the conventional practice of FIG. 3. A preferred method addresses the narrow target erosion problem and maximizes the use of target material. In a preferred method, the magnet assembly is mounted on a two dimensional motion stage as shown in the schematic in FIG. 5. This design embodies two independently operated linear motion stages 62 and 68 capable of independently moving along two orthogonal directions named as X and Y direction, X being the horizontal and Y being the vertical direction.

Preferably, a computer 70, such as a PC, controls the XY stage motion by controlling the electronic control unit 72 through an interface 74 such as a RS 232 interface. As will now be recognized by a person of ordinary skill in the art, control software could be the XY stage vendor supplied control software, custom written software in Labview, and the like. Preferably, speed and the span of the motion can be independently varied for both X and Y directions from a computer so that motion of the magnet 78 in any two dimensional paths is possible. In a most preferred embodiment, the magnet motion can be easily started just by entering the coordinates (relative to pre-defined origin) of the path of interest and the maximum linear speed along X or Y direction into the associated computer software. The motion can be repeated for any number of times, 1 to infinity as required.

To create the desired profile on the target as shown in FIG. 4, a magnet assembly is designed with appropriate dimensions in a manner such as will now be understood by a person of skill in the art in light of this specification. If d is the separation between the deepest region of the race track in a direction perpendicular to the long side of the rectangular target 30 while the magnet is static and positioned symmetrically with respect to the target's edges, then the size and the amplitude of the magnet motion in a direction perpendicular to this side of the target preferably provides that the centerlines of the plasmas from either sides just overlap at the middle line on the target surface. In such a case, the plasma strips preferably move d/2 in the either sides from their original position as shown in FIG. 6. By employing this technique the evenly eroded groove width in this direction will be at least 2d with slightly tapered walls. If the plasmas go too far crossing this middle line then the middle region will be eroded faster than any place else and if the centerlines of the plasmas do not meet at the middle line then there will be less erosion from the middle region causing a mound to be formed here. Once a slightly deeper region is created anywhere, the magnetic field in this region becomes higher than anywhere else because of thinner target in this region, which makes the trapping of the electrons more efficient in this region further causing even faster erosion. To avoid such a chain reaction, the target is preferably evenly eroded from the very beginning. As will be understood by a person of skill in the art, this requires a carefully controlled magnet assembly and motion path.

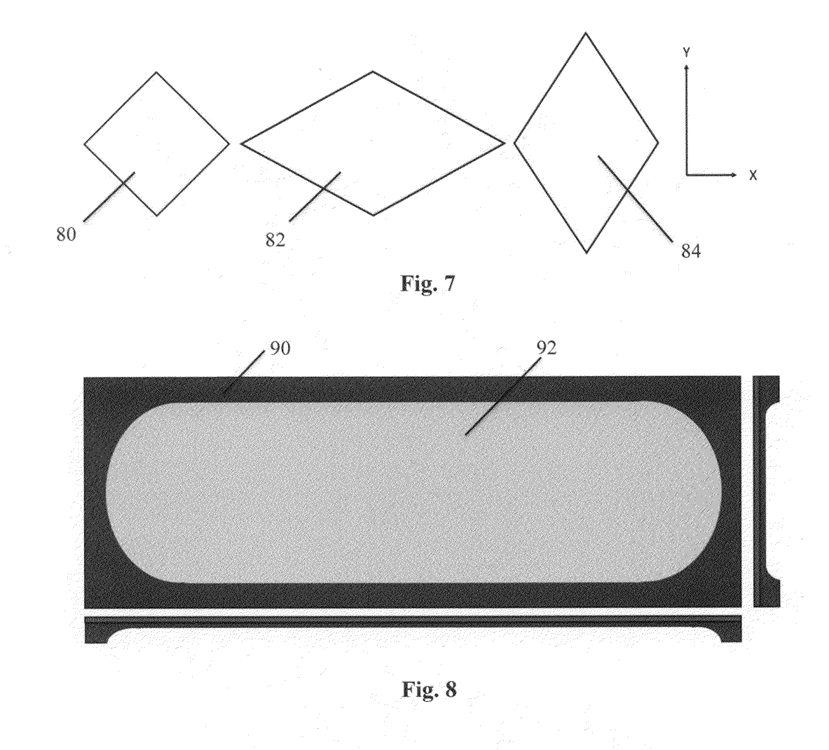

The two dimensional motion of the magnet at any point in time is preferably not parallel to the X or Y direction, but rather at an angle to avoid any locally faster erosion of the target. A set of preferred magnet motion paths include a rhombus 80 or elongated rhombus 82 and 84 such as the examples shown in FIG. 7. Depending upon the dimensions of the target and the safety lines around the edges of the target up to which the plasma can safely reach without causing any arcing events at the edges or sputtering materials from non-target environments, the ratio for the X to Y amplitude can be determined. By moving the magnet designed according to the guidelines given in the previous paragraph along these paths, most of the target 90 in the middle region 92 can be evenly eroded except some small regions at the four corners. However, since one of the X or the Y stage reverse the direction of its motion at the corner of the rhombus in some embodiments, there is going to be slightly faster eroded regions at the corners. Preferably, this effect can be minimized by adjusting the speed (going slightly faster) of the corresponding stages at these points. Utilizing the techniques of the preferred embodiments of the present invention, at the optimal conditions the target erosion profile can look like as shown in FIG. 8, which is little different to the desired profile given in FIG. 4.

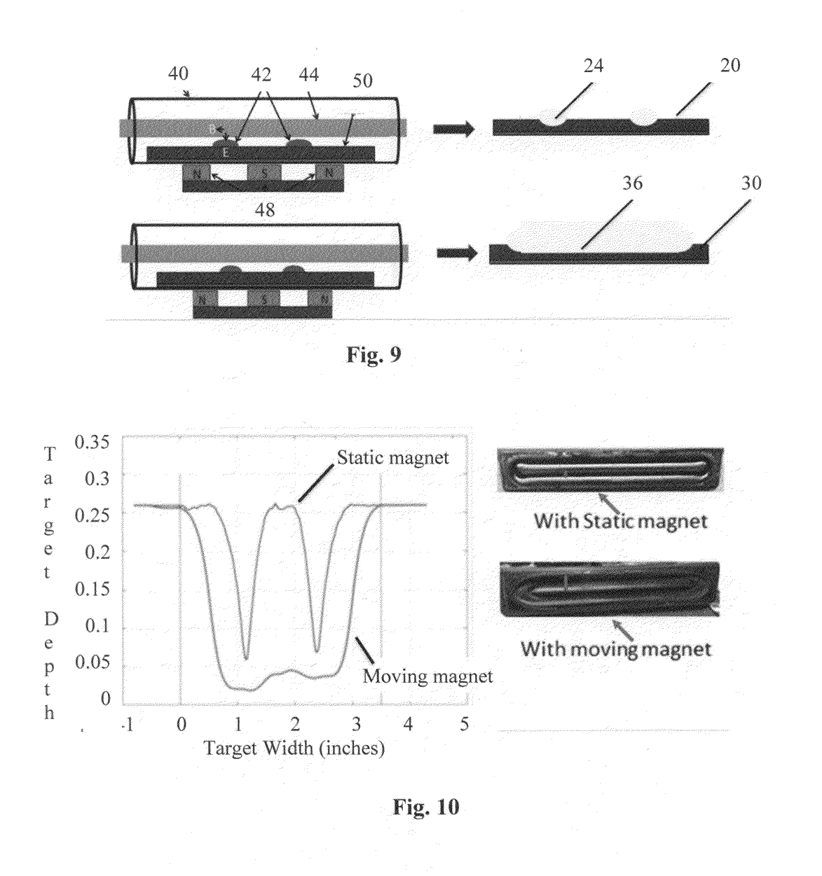

FIGS. 9 and 10 depict further comparisons of the profile of targets from conventional systems and embodiments of the present invention. As can be seen in FIG. 9, by moving a magnet assembly of appropriate size along an optimal path, the target 30 use can be increased significantly by sputtering almost all the middle portion 36 of the target 30. FIG. 10 depicts a graphic of simulated target erosion profile for a moving magnet assembly in accord with the present invention compared with the profile of a typical static magnet assembly. Simulations show that target use can be increased by more than four times using the moving magnet assembly. As will be recognized by those of skill in the art, such an increase in target use can significantly reduce costs. The photographic comparison of the conventional static magnet systems with the moving magnet embodiment show significant improvements. As will be recognized, the size of the magnet assembly needs to be optimized to sputter off the narrow region left in the middle in this test sample.

While the terms used herein are believed to be well-understood by one of ordinary skill in the art, definitions are set forth to facilitate explanation of certain of the presently-disclosed subject matter.

Following long-standing patent law convention, the terms “a”, “an”, and “the” refer to one or more when used in this application, including the claims. Thus, for example, reference to “a window” includes a plurality of such windows, and so forth.

Unless otherwise indicated, all numbers expressing quantities of elements, dimensions such as width and area, and so forth used in the specification and claims are to be understood as being modified in all instances by the term “about”. Accordingly, unless indicated to the contrary, the numerical parameters set forth in this specification and claims are approximations that can vary depending upon the desired properties sought to be obtained by the presently-disclosed subject matter.

As used herein, the term “about,” when referring to a value or to an amount of a dimension, area, percentage, etc., is meant to encompass variations of in some embodiments plus or minus 20%, in some embodiments plus or minus 10%, in some embodiments plus or minus 5%, in some embodiments plus or minus 1%, in some embodiments plus or minus 0.5%, and in some embodiments plus or minus 0.1% from the specified amount, as such variations are appropriate to perform the disclosed methods or employ the disclosed compositions.

The term “comprising”, which is synonymous with “including” “containing” or “characterized by” is inclusive or open-ended and does not exclude additional, unrecited elements or method steps. “Comprising” is a term of art used in claim language which means that the named elements are essential, but other elements can be added and still form a construct within the scope of the claim.

As used herein, the phrase “consisting of” excludes any element, step, or ingredient not specified in the claim. When the phrase “consists of” appears in a clause of the body of a claim, rather than immediately following the preamble, it limits only the element set forth in that clause; other elements are not excluded from the claim as a whole.

As used herein, the phrase “consisting essentially of” limits the scope of a claim to the specified materials or steps, plus those that do not materially affect the basic and novel characteristic(s) of the claimed subject matter. With respect to the terms “comprising”, “consisting of”, and “consisting essentially of”, where one of these three terms is used herein, the presently disclosed and claimed subject matter can include the use of either of the other two terms.

As used herein, the term “and/or” when used in the context of a listing of entities, refers to the entities being present singly or in combination. Thus, for example, the phrase “A, S, C, and/or O” includes A, S, C, and O individually, but also includes any and all combinations and subcombinations of A, S, C, and O.

It will be apparent to those skilled in the art that various modifications and variations can be made in the present invention without departing from the scope or spirit of the invention. Other embodiments of the invention will be apparent to those skilled in the art from consideration of the specification and practice of the invention disclosed herein. The foregoing disclosure and description are illustrative and explanatory thereof, and various changes in the details of the illustrated apparatus and construction and method of operation may be made without departing from the spirit in scope of the invention which is described by the following claims.

I claim the following:

1. An improved process for sputtering a coating using a magnetron sputtering apparatus comprising the steps of:
(1) moving a magnet assembly in two dimensions during the sputtering process resulting in increased erosion area of a target as compared to stationary magnets.

2. The process of claim 1, wherein the two dimensional movement comprises movement in the horizontal and vertical directions.

3. The process of claim 1, further comprising the step of providing two independently operated motion stages capable of independent movement along two orthogonal directions, prior to the moving a magnet step.

4. The process of claim 1, wherein the movement comprises movement at an angle compared to both directions.

5. The process of claim 1, wherein the motion path of the moving magnet comprises a rhombus shaped motion path.

6. The process of claim 1, wherein the motion path of the moving magnet comprises an elongated rhombus shaped motion path.

7. The process of claim 1, wherein the process increases the erosion of target material at least two times that of stationary magnets.

8. The process of claim 1, wherein the process increases the erosion of target material at least four times that of stationary magnets.

9. An improved magnetron sputtering apparatus comprising:
a first motion stage providing movement in a first direction;
a second motion stage providing movement in second direction;
a magnet assembly operably attached to said first and second motion stages; and
a control unit.

10. The apparatus of claim 9 wherein the first motion stage provides movement horizontally.

11. The apparatus of claim 9 wherein the second motion stage provides movement vertically.

12. The apparatus of claim 9 further comprising a computer having control software, and an interface between the computer and the control unit.

13. The apparatus of claim 9 wherein the control unit controls movement of the magnet assembly along a movement path having a generally rhombus shape.

14. The apparatus of claim 9 wherein the control unit controls movement of the magnet assembly along a movement path having a generally elongated rhombus shape.

15. The apparatus of claim 9 wherein the control unit controls movement of the magnet assembly along a path having an oblique angle relative to the horizontal direction.

16. The apparatus of claim 9 wherein the control unit controls movement of the magnet assembly along a path having an oblique angle relative to the vertical direction.
